(19) United States
(12) Patent Application Publication
(10) Pub. No.: US 2024/0388255 A1
(43) Pub. Date: Nov. 21, 2024

(54) RADIO FREQUENCY AMPLIFIER CIRCUIT AND RADIO FREQUENCY AMPLIFIER DEVICE

(71) Applicant: Sumitomo Electric Device Innovations, Inc., Yokohama-shi (JP)

(72) Inventor: Takuma MORI, Yokohama-shi (JP)

(73) Assignee: Sumitomo Electric Device Innovations, Inc., Yokohama-shi (JP)

(21) Appl. No.: 18/661,915

(22) Filed: May 13, 2024

(30) Foreign Application Priority Data
May 15, 2023 (JP) 2023-080214

(51) Int. Cl. H03F 1/02; H03F 3/24

(52) U.S. Cl. CPC H03F 1/0288; H03F 3/245; H03F 2200/451

(57) ABSTRACT

A radio frequency amplifier circuit includes a Doherty amplifier including a main amplifier and a peak amplifier. The main amplifier includes a first input end, a first output end, and a first transistor. The main amplifier includes only a first harmonic processing circuit among the first harmonic processing circuit and a first fundamental matching circuit. The peak amplifier includes a second input end, a second output end, and a second transistor. The peak amplifier includes only a second fundamental matching circuit among a second harmonic processing circuit and the second fundamental matching circuit.

### REFERENCE TO RELATED APPLICATIONS

This application claims priority based on Japanese Patent Application No. 2023-080214 filed on May 15, 2023, and the entire contents of the Japanese patent application are incorporated herein by reference.

### TECHNICAL FIELD

The present disclosure relates to a radio frequency amplifier circuit and a radio frequency amplifier device.

### BACKGROUND OF THE INVENTION

In PTL 1, a technique related to a Doherty amplifier is disclosed. The Doherty amplifier is constituted by a carrier amplifier that amplifies an input signal and a peak amplifier that amplifies only a peak component of the input signal. In this Doherty amplifier, the carrier amplifier and the peak amplifier are mounted on a substrate, and the carrier amplifier and the peak amplifier are covered with a package.
PTL 1: Japanese Unexamined Patent Application Publication No. 2005-210224

### SUMMARY OF THE INVENTION

A radio frequency amplifier circuit according to an embodiment of the present disclosure is a radio frequency amplifier circuit includes a Doherty amplifier including a main amplifier and a peak amplifier. The main amplifier includes a first input end, a first output end, a first transistor having a control terminal connected to the first input end and a current terminal connected to the first output end. The main amplifier includes only a first harmonic processing circuit among the first harmonic processing circuit and a first fundamental matching circuit, the first harmonic processing circuit being connected to the control terminal of the first transistor and configured to suppress a harmonic to be input to the first transistor, the first fundamental matching circuit being connected between the first input end and the control terminal of the first transistor and configured to attain matching with an input impedance of the first transistor. The peak amplifier includes a second input end, a second output end, a second transistor having a control terminal connected to the second input end and a current terminal connected to the second output end. The peak amplifier includes only a second fundamental matching circuit among a second harmonic processing circuit and the second fundamental matching circuit, the second harmonic processing circuit being connected to the control terminal of the second transistor and configured to suppress a harmonic to be input to the second transistor, the second fundamental matching circuit being connected between the second input end and the control terminal of the second transistor and configured to attain matching with an input impedance of the second transistor.

### BRIEF DESCRIPTION OF THE DRAWINGS

FIG. 1 is a circuit diagram showing a radio frequency amplifier circuit according to a first embodiment of the present disclosure.

FIG. 2 is a plan view schematically showing a radio frequency amplifier device according to a second embodiment of the present disclosure.

FIG. 3 is a cross-sectional view along line III-III shown in FIG. 2.

FIG. 4 is a cross-sectional view along line IV-IV shown in FIG. 2.

FIG. 5 is a plan view showing a radio frequency amplifier device according to a first modification of a second embodiment.

FIG. 6 is a Smith chart showing impedance characteristics in a first modification of FIG. 5.

FIG. 7 is a plan view showing a radio frequency amplifier device according to a second modification.

FIG. 8 is a plan view showing a radio frequency amplifier device according to a third modification.

FIG. 9 is an enlarged view showing the configuration of an integrated passive device.

FIG. 10 is a cross-sectional view along line X-X shown in FIG. 9.

FIG. 11 is a plan view showing a radio frequency amplifier device according to a fourth modification.

FIG. 12 is a plan view showing a radio frequency amplifier device according to a fifth modification.

FIG. 13 is an enlarged view showing a modification of an integrated passive device.

FIG. 14 is a cross-sectional view along line XIV-XIV shown in FIG. 13.

FIG. 15 is a circuit diagram showing a radio frequency amplifier circuit, which is a comparative example.

FIG. 16 is a plan view schematically showing a radio frequency amplifier device, which is a comparative example.

### DETAILED DESCRIPTION

For example, an amplifier for amplifying an input signal is one of the components of a communication base station device. As the amount of communication increases, a Doherty amplifier that has a wide output range and operates with high efficiency is adopted as the amplifier. In the communication base station device having the Doherty amplifier, the challenge is to miniaturize the device while maintaining high amplification efficiency.

An object of the present disclosure is to provide a radio frequency amplifier circuit and a radio frequency amplifier device that can be miniaturized while maintaining high amplification efficiency.

### Description of Embodiments of Present Disclosure

First, the contents of embodiments of the present disclosure will be listed and explained. [1] A radio frequency amplifier circuit according to an embodiment of the present disclosure is a radio frequency amplifier circuit includes a Doherty amplifier including a main amplifier and a peak amplifier. The main amplifier includes a first input end, a first output end, a first transistor having a control terminal connected to the first input end and a current terminal connected to the first output end. The main amplifier includes only a first harmonic processing circuit among the first harmonic processing circuit and a first fundamental matching circuit, the first harmonic processing circuit being connected to the control terminal of the first transistor and configured to suppress a harmonic to be input to the first transistor, the first fundamental matching circuit being connected between the first input end and the control terminal of the first transistor and configured to attain matching with an input impedance of the first transistor. The peak amplifier includes a second input end, a second output end, a second transistor having a control terminal connected to the second input end and a current terminal connected to the second output end. The peak amplifier includes only a second fundamental matching circuit among a second harmonic processing circuit and the second fundamental matching circuit, the second harmonic processing circuit being connected to the control terminal of the second transistor and configured to suppress a harmonic to be input to the second transistor, the second fundamental matching circuit being connected between the second input end and the control terminal of the second transistor and configured to attain matching with an input impedance of the second transistor.

The main amplifier of the Doherty amplifier operates at all times. The peak amplifier operates when an output larger than a saturation output of the main amplifier is required. The main amplifier includes a class A amplifier circuit, a class AB amplifier circuit, or a class B amplifier circuit. Therefore, the main amplifier operates with lower efficiency than an amplifier having a class C amplifier circuit. Therefore, by providing the first harmonic processing circuit in the main amplifier, the harmonic input to the main amplifier is suppressed. By suppressing the harmonic, the decrease in the operation efficiency in the main amplifier is reduced. The peak amplifier includes a class C amplifier circuit. Further, the peak amplifier operates when an output larger than the saturation output of the main amplifier is required. Therefore, the peak amplifier can be operated with high efficiency without providing the second harmonic processing circuit in the peak amplifier. However, since the output of the peak amplifier is large, the mismatch of the input impedance of the second transistor becomes large. Therefore, the amplification efficiency of the peak amplifier is reduced. Therefore, a second fundamental matching circuit is provided in the peak amplifier. The second fundamental matching circuit is connected between the second input end and the control terminal of the second transistor, thereby suppressing the mismatch of the input impedance of the second transistor. Thus, the reduction in the amplification efficiency in the peak amplifier is suppressed. Therefore, the reduction in the amplification efficiency in the main amplifier and the peak amplifier is suppressed, and the radio frequency amplifier circuit can be operated while maintaining higher efficiency. Only the first harmonic processing circuit is provided on the input side of the main amplifier. Only the second fundamental matching circuit is provided on the input side of the peak amplifier. This reduces the number of circuits to be mounted and the surface area of the radio frequency amplifier circuit. Therefore, the radio frequency amplifier circuit can be further miniaturized.

[2] The first harmonic processing circuit of the radio frequency amplifier circuit according to above [1] may include a first capacitor having one electrode connected to a reference potential, and a first wire configured to connect another electrode of the first capacitor with the control terminal of the first transistor and including a first inductance. The second fundamental matching circuit may include a second capacitor having one electrode connected to the reference potential, a second wire configured to connect another electrode of the second capacitor with the second input end and including a second inductance, and a third wire configured to connect the control terminal of the second transistor with the another electrode of the second capacitor and including a third inductance. The first capacitor and the first inductance are connected in series. Thus, the first capacitor and the first inductance resonate with each other, and a high frequency input to the main amplifier can be suppressed. The second capacitor, the second inductance, and the third inductance match a reactance component included in the input impedance of the second transistor. This can reduce the mismatch between the input impedance of the second transistor and the impedances of the second wire and the third wire. Therefore, the reduction in the amplification efficiency in the main amplifier and the peak amplifier is suppressed, and the radio frequency amplifier circuit can be operated while maintaining higher efficiency.

[3] A radio frequency amplifier device according to an embodiment of the present disclosure is a radio frequency amplifier device includes a Doherty amplifier including a main amplifier and a peak amplifier. The main amplifier includes a first input end, a first output end, a first transistor having a control terminal connected to the first input end and a current terminal connected to the first output end. The main amplifier includes only a first harmonic processing element among the first harmonic processing element and a first fundamental matching element, the first harmonic processing element being connected to the control terminal of the first transistor and configured to suppress a harmonic to be input to the first transistor, the first fundamental matching element being connected between the first input end and the control terminal of the first transistor and configured to attain matching with an input impedance of the first transistor. The peak amplifier includes a second input end, a second output end, a second transistor having a control terminal connected to the second input end and a current terminal connected to the second output end. The peak amplifier includes only a second fundamental matching element among a second harmonic processing element and the second fundamental matching element, the second harmonic processing element being connected to the control terminal of the second transistor and configured to suppress a harmonic to be input to the second transistor, the second fundamental matching element being connected between the second input end and the control terminal of the second transistor and configured to attain matching with an input impedance of the second transistor.

The main amplifier of the Doherty amplifier operates at all times. The peak amplifier operates when an output larger than the saturation output of the main amplifier is required. The main amplifier has a class A amplifier circuit, a class AB amplifier circuit, or a class B amplifier circuit. Therefore, the main amplifier operates with lower efficiency than an amplifier having a class C amplifier circuit. Therefore, by providing the first harmonic processing element in the main amplifier, the harmonic input to the main amplifier is suppressed. By suppressing the harmonic, the decrease in the operation efficiency in the main amplifier is reduced. The peak amplifier has a class C amplifier circuit. Further, the peak amplifier operates when an output larger than the saturation output of the main amplifier is required. Therefore, the peak amplifier can be operated with high efficiency without providing the second harmonic processing element in the peak amplifier. However, since the output of the peak amplifier is large, the mismatch of the input impedance of the second transistor becomes large. Therefore, the amplification efficiency of the peak amplifier is reduced. Therefore, a second fundamental matching element is provided in the peak amplifier. The second fundamental matching element is connected between the second input end and the control terminal of the second transistor, thereby suppressing the mismatch of the input impedance of the second transistor. Thus, the reduction in the amplification efficiency in the peak amplifier is suppressed. Therefore, the reduction in the amplification efficiency in the main amplifier and the peak amplifier is suppressed, and the radio frequency amplifier device can be operated while maintaining higher efficiency. Only the first harmonic processing element is provided on the input side of the main amplifier. Only the second fundamental matching element is provided on the input side of the peak amplifier. This reduces the number of elements to be mounted and the surface area of the radio frequency amplifier device. Therefore, the radio frequency amplifier device can be further miniaturized.

[4] An output of the peak amplifier of radio frequency amplifier device according to above [3] may be larger than an output of the main amplifier. This is because the output of the peak amplifier is larger than the output of the main amplifier, and thus the Doherty amplifier can operate with high efficiency in a wider output range.

[5] The main amplifier of the radio frequency amplifier device according to above [4] may include a fourth wire configured to make a connection between the first output end and the current terminal of the first transistor. The peak amplifier may include a fifth wire configured to make a connection between the second output end and the current terminal of the second transistor. The fourth wire has a length longer than a length of the fifth wire. This facilitates impedance matching when the output of the peak amplifier is larger than the output of the main amplifier.

[6] The first harmonic processing element of the radio frequency amplifier device according to above [3], [4], or [5] may be disposed between the first transistor and the peak amplifier. The first harmonic processing element is disposed between the first transistor and the peak amplifier, and thus it is possible to reduce the interval between the first transistor and the first input end. Therefore, the radio frequency amplifier device can be further miniaturized.

[7] The main amplifier of the radio frequency amplifier device according to above [5] may include a first wire configured to make a connection between the control terminal of the first transistor and the first harmonic processing element, and a sixth wire configured to make a connection between the first input end and the control terminal of the first transistor. A direction in which the first wire extends and a direction in which the sixth wire extends cross in plan view. With such an arrangement, the line capacitance between the first wire and the sixth wire is suppressed. This makes it possible to suppress line loss in the first wire and the sixth wire. Therefore, it is possible to operate the radio frequency amplifier device while maintaining higher efficiency.

[8] The radio frequency amplifier device according to above [6] or [7] may include an integrated passive device including the first harmonic processing element and the second fundamental matching element. This reduces the surface area of the elements included in the radio frequency amplifier device, and thus the radio frequency amplifier device can be further miniaturized.

[9] The integrated passive device of the radio frequency amplifier device according to above [8] may include a substrate, a second metal film and a fourth metal film that are provided on one surface of the substrate, a dielectric film provided on the second metal film and the fourth metal film, and a first metal film and a third metal film that are provided on the dielectric film. The first harmonic processing element is constituted by the second metal film, the dielectric film, and the first metal film. The second fundamental matching element is constituted by the fourth metal film, the dielectric film, and the third metal film. The first metal film and the control terminal of the first transistor are connected to each other. The third metal film and the control terminal of the second transistor are connected to each other. The second metal film and the fourth metal film are connected to a reference potential.

The first metal film, the second metal film, and the dielectric film form a capacitor with the potential of the second metal film as a reference. The first harmonic processing element includes the capacitor. The third metal film, the fourth metal film, and the dielectric film form a capacitor with the potential of the fourth metal film as a reference. The second fundamental matching element includes the capacitor. The first harmonic processing element and the second fundamental matching element are provided on one surface of the substrate. Thus, the integrated passive device can be realized.

The integrated passive device of the radio frequency amplifier device according to above [9] may include a fifth metal film provided on the one surface between the first harmonic processing element and the second fundamental matching element and connected to the reference potential. By providing the fifth metal film connected to the reference potential between the first harmonic processing element and the second fundamental matching element, it is possible to suppress electromagnetic interference between the main amplifier and the peak amplifier.

The integrated passive device of the radio frequency amplifier device according to above may include a via provided in the substrate and connected to the fifth metal film, and a back-side metal film provided on a surface opposite to the one surface and connected to the via and the reference potential. The fifth metal film and the via are connected to each other, and the via and the back-side metal film connected to the reference potential are connected to each other. As a result, the potential of the fifth metal film becomes a reference potential.

### Details of Embodiments of Present Disclosure

Specific examples of the radio frequency amplifier circuit and the radio frequency amplifier device of the present disclosure will be described below with reference to the drawings. The present invention is not limited to these examples, but is defined by the scope of the claims, and is intended to include all modifications within the meaning and scope equivalent to the scope of the claims. In the following description, the same elements are denoted by the same reference numerals in the description of the drawings, and the overlapping description will be omitted. In the following description, the term “connected” means “electrically connected”, and unless otherwise specified, includes not only the case of being connected via a conductive wire having an electrical resistance of substantially zero, but also the case of being connected via an electronic component such as a resistor. The control terminal is a gate when the transistor is an FET, and is a base when the transistor is a bipolar transistor. The current terminal is a source or a drain in the case where the transistor is an FET, and is an emitter or a collector in the case where the transistor is a bipolar transistor.

### First Embodiment

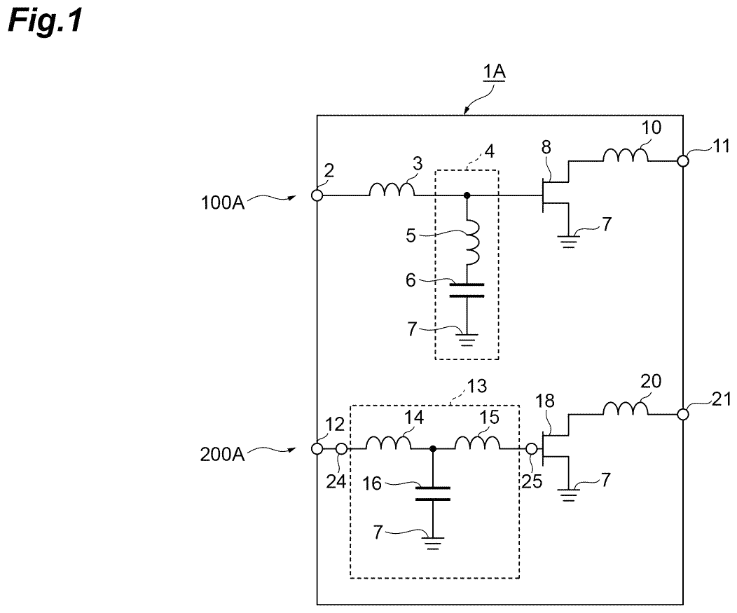

FIG. 1 is a circuit showing of a radio frequency amplifier circuit 1A according to a first embodiment of the present disclosure. Referring to FIG. 1, radio frequency amplifier circuit 1A according to the first embodiment of the present disclosure will be described. Radio frequency amplifier circuit 1A is a so-called Doherty amplifier. The frequencies of the signals input to the Doherty amplifier are, for example, from 60 GHz to 90 GHz. As shown in FIG. 1, radio frequency amplifier circuit 1A includes a main amplifier 100A and a peak amplifier 200A.

Main amplifier 100A includes a first input end 2, a first output end 11, and a first transistor 8. The control terminal of first transistor 8 and first input end 2 are connected to each other, and one current terminal of first transistor 8 and first output end 11 are connected to each other. The other current terminal of first transistor 8 is connected to a reference potential line 7. Main amplifier 100A includes only a first harmonic processing circuit 4 among first harmonic processing circuit 4 and the first fundamental matching circuit, first harmonic processing circuit 4 being connected to the control terminal of first transistor 8 and configured to suppress a harmonic to be input to first transistor 8, the first fundamental matching circuit being connected between first input end 2 and the control terminal of first transistor 8 and configured to attain matching with an input impedance of first transistor 8. A wire 3 is connected between first input end 2 and the control terminal of first transistor 8, and is interposed between first input end 2 and the control terminal of first transistor 8. A wire 10 (fourth wire) is connected between one current terminal of first transistor 8 and first output end 11, and is interposed between the one current terminal of first transistor 8 and first output end 11. Wire 3 and wire 10 include inductance at the signal frequency. First input end 2 is, for example, an input terminal. First output end 11 is, for example, an output terminal. Main amplifier 100A is an A class amplifier circuit, an AB class amplifier circuit, or a B class amplifier circuit.

Peak amplifier 200A includes a second input end 12, a second output end 21, and a second transistor 18. The control terminal of second transistor 18 and second input end 12 are connected to each other. One current terminal of second transistor 18 and second output end 21 are connected to each other. The other current terminal of second transistor 18 is connected to reference potential line 7. Peak amplifier 200A includes only a second fundamental matching circuit 13 among a second harmonic processing circuit and second fundamental matching circuit 13, the second harmonic processing circuit being connected to the control terminal of second transistor 18 and configured to suppress a harmonic to be input to second transistor 18, second fundamental matching circuit 13 being connected between second input end 12 and the control terminal of second transistor 18 and configured to attain matching with an input impedance of second transistor 18. Second fundamental matching circuit 13 is connected between second input end 12 and the control terminal of second transistor 18, and attains matching with the input impedance of second transistor 18. Second input end 12 and an input end 24 of second fundamental matching circuit 13 are connected to each other. An output end 25 of second fundamental matching circuit 13 and the control terminal of second transistor 18 are connected to each other. A wire 20 (fifth wire) is connected between one current terminal of second transistor 18 and second output end 21, and is interposed between the one current terminal of second transistor 18 and second output end 21. Wire 20 includes inductance at the signal frequency. Second input end 12 is, for example, an input terminal. Second output end 21 is, for example, an output terminal. Peak amplifier 200A is a class C amplifier circuit.

First harmonic processing circuit 4 includes a first capacitor 6 and a wire 5 (first wire). One electrode of first capacitor 6 is connected to reference potential line 7. Wire 5 is connected between the other electrode of first capacitor 6 and the control terminal of first transistor 8. Wire 5 includes inductance at the signal frequency. The capacitance of first capacitor 6 is, for example, from 0.1 pF to 1 pF.

Second fundamental matching circuit 13 includes a second capacitor 16, a wire 14 (second wire), and a wire 15 (third wire). One electrode of second capacitor 16 is connected to reference potential line 7. Wire 14 is connected between the other electrode of second capacitor 16 and second input end 12. Wire 15 is connected between the control terminal of second transistor 18 and the other electrode of second capacitor 16. Wire 14 and wire 15 include inductance at the signal frequency. The capacitance of second capacitor 16 is, for example, from 1 pF to 10 pF.

The operation of main amplifier 100A having the above configuration will be described. Main amplifier 100A operates at all times. A signal input from first input end 2 is input to the control terminal of first transistor 8. In first harmonic processing circuit 4, first capacitor 6 and wire 5 resonate. When the signal is input to the control terminal, the harmonic included in the signal is suppressed by the resonance of first harmonic processing circuit 4. Next, first transistor 8 amplifies the signal whose harmonic is suppressed, and the amplified signal is output from first output end 11.

Peak amplifier 200A operates when an output larger than the saturation output of main amplifier 100A is required. The signal input from second input end 12 is input to the control terminal of second transistor 18. The signal is amplified by second transistor 18 and output from second input end 21. In second fundamental matching circuit 13 provided on the input side of second transistor 18, second capacitor 16, wire 14, and wire 15 match the reactance component included in the input impedance of second transistor 18.

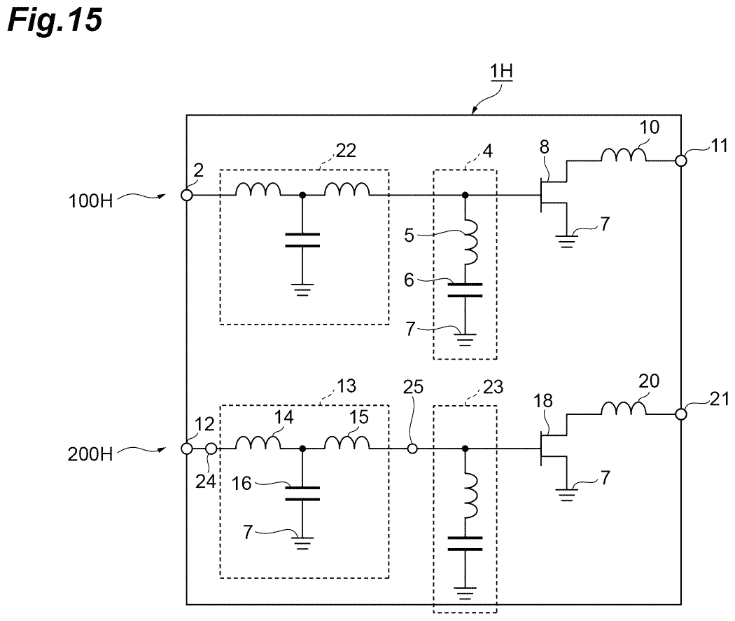

The effects of main amplifier 100A and peak amplifier 200A having the above configurations will be described with reference to FIG. 15. FIG. 15 is a circuit diagram showing a radio frequency amplifier circuit 1H, which is a comparative example. Radio frequency amplifier circuit 1H includes a main amplifier 100H and a peak amplifier 200H. Main amplifier 100H has both first harmonic processing circuit 4 and a first fundamental matching circuit 22 on the input side. Peak amplifier 200H includes both a second harmonic processing circuit 23 and second fundamental matching circuit 13 on the input side. Main amplifier 100H maintains high amplification efficiency by both first harmonic processing circuit 4 and first fundamental matching circuit 22. Peak amplifier 200H maintains high amplification efficiency by both second harmonic processing circuit 23 and second fundamental matching circuit 13. Compared with the Doherty amplifier having such a configuration, it is an object to provide a Doherty amplifier being downsized as well as maintaining high amplification efficiency. The efficiency of the main amplifier, which is a class A, class AB, or class B amplifier circuit, is lower than that of the amplifier, which is a class C amplifier circuit. Further, since the main amplifier is driven in the entire power range, the efficiency is likely to be reduced when the modulation signal is amplified. Therefore, in radio frequency amplifier circuit 1A according to the first embodiment of the present disclosure, the harmonic input to main amplifier 100A is suppressed by providing first harmonic processing circuit 4 in main amplifier 100A. Thus, the efficiency of main amplifier 100A is less likely to be reduced. This is because the output of the main amplifier is generally small, and therefore, the input impedance matching can be easily achieved, and the main amplifier can operate with high efficiency without providing a fundamental matching circuit in the main amplifier. On the other hand, the peak amplifier is a class C amplifier circuit, and thus has high efficiency. Therefore, peak amplifier 200A can operate with high efficiency without being provided with second harmonic processing circuit 23. However, since the output of the peak amplifier is generally large, the mismatch of the input impedance of the transistor tends to be large. Therefore, the amplification efficiency of the peak amplifier is likely to decrease. Therefore, in the embodiment, second fundamental matching circuit 13 is provided in peak amplifier 200A. This suppresses a reduction in the amplification efficiency in peak amplifier 200A. Therefore, the reduction in the amplification efficiency in main amplifier 100A and peak amplifier 200A is suppressed, and radio frequency amplifier circuit 1A can be operated while maintaining high efficiency. Further, only first harmonic processing circuit 4 is provided on the input side of main amplifier 100A, and only second fundamental matching circuit 13 is provided on the input side of peak amplifier 200A. This reduces the size of the circuit to be mounted and reduces the surface area of radio frequency amplifier circuit 1A. Therefore, radio frequency amplifier circuit 1A can be further miniaturized.

### Second Embodiment

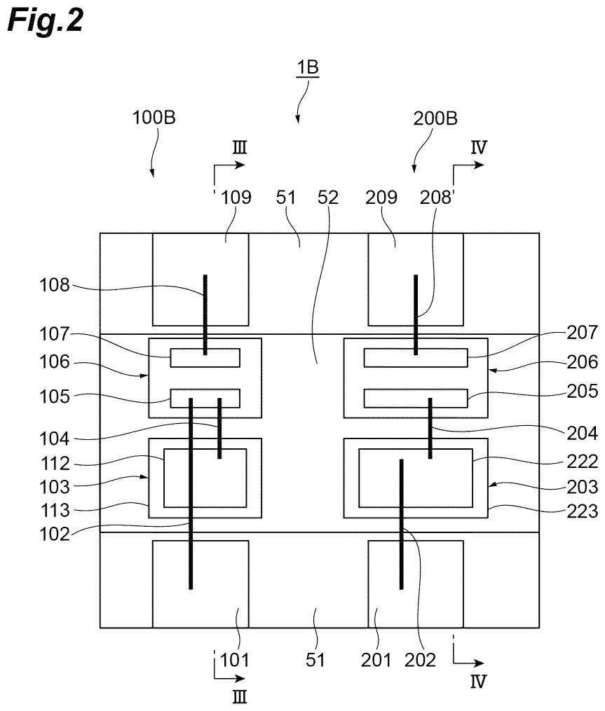

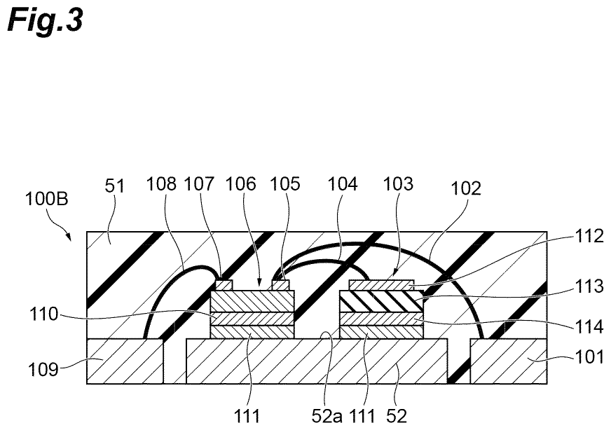

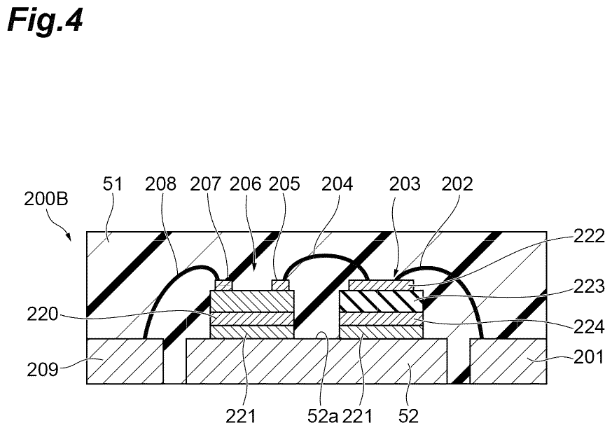

FIG. 2 is a plan view schematically showing a radio frequency amplifier device 1B according to a second embodiment of the present disclosure. Radio frequency amplifier device 1B is a device obtained by making radio frequency amplifier circuit 1A of FIG. 1 into a device, and has a rectangular parallelepiped shape. Radio frequency amplifier device 1B has a main amplifier 100B and a peak amplifier 200B. FIG. 3 is a cross-sectional view along line III-III shown in FIG. 2. FIG. 4 is a cross-sectional view along line IV-IV shown in FIG. 2.

Main amplifier 100B includes a first input end 101, a first output end 109, and a first transistor 106. Main amplifier 100B corresponds to main amplifier 100A in FIG. 1. First input end 101 corresponds to first input end 2 in FIG. 1. First output end 109 corresponds to first output end 11 in FIG. 1. First transistor 106 corresponds to first transistor 8 in FIG. 1. A control terminal 105 of first transistor 106 and first input end 101 are connected to each other, and a current terminal 107 of first transistor 106 and first output end 109 are connected to each other. Main amplifier 100B includes only a first harmonic processing element 103 among first harmonic processing element 103 and a first fundamental matching element, first harmonic processing element 103 being connected to control terminal 105 of first transistor 106 and configured to suppress a harmonic to be input to first transistor 106, the first fundamental matching element being connected between first input end 101 and control terminal 105 of first transistor 106 and configured to attain matching with an input impedance of first transistor 106. First harmonic processing element 103 corresponds to first harmonic processing circuit 4 of FIG. 1. Main amplifier 100B is provided in a package having a rectangle shape in plan view, for example. First harmonic processing element 103 and first transistor 106 are arranged in this order from first input end 101 and between first input end 101 and first output end 109. First input end 101 is, for example, an input terminal. First output end 109 is, for example, an output terminal.

Peak amplifier 200B includes a second input end 201, a second output end 209, and a second transistor 206. Peak amplifier 200B corresponds to peak amplifier 200A in FIG. 1. Second input end 201 corresponds to second output end 12 in FIG. 1. Second output end 209 corresponds to second output end 21 in FIG. 1. Second transistor 206 corresponds to second transistor 18 of FIG. 1. A control terminal 205 of second transistor 206 and second input end 201 are connected to each other. A current terminal 207 of second transistor 206 and second output end 209 are connected to each other. Peak amplifier 200B includes only a second fundamental matching element 203 among the second harmonic processing element and second fundamental matching element 203, the second harmonic processing element being connected to control terminal 205 of second transistor 206 and configured to suppress a harmonic to be input to second transistor 206, second fundamental matching element 203 being connected between second input end 201 and control terminal 205 of second transistor 206 and configured to attain matching with an input impedance of second transistor 206. Second fundamental matching element 203 corresponds to second fundamental matching circuit 13 in FIG. 1. Peak amplifier 200B is provided in a package common to main amplifier 100B. Between second input end 201 and second output end 209, second fundamental matching element 203 and second transistor 206 are arranged in this order from second input end 201. Second input end 201 is, for example, an input terminal. Second output end 209 is, for example, an output terminal.

Main amplifier 100B and peak amplifier 200B are sealed by, for example, a scaling material 51. Sealing material 51 is, for example, a mold resin.

As shown in FIG. 2, first harmonic processing element 103 has a rectangle shape in plan view and is disposed between first input end 101 and first transistor 106. As shown in FIG. 3, first harmonic processing element 103 has a front-side metal film 112, a dielectric 113, and a back-side metal film 114. Front-side metal film 112 is provided on one surface of dielectric 113. Back-side metal film 114 is provided on the other surface of dielectric 113. The cross-sectional shape of first harmonic processing element 103 is substantially rectangular. First harmonic processing element 103 constitutes a capacitor in which front-side metal film 112 is one electrode and back-side metal film 114 is the other electrode. A capacitance C of the capacitor is, for example, from 0.1 pF to 1 pF. This capacitor corresponds to first capacitor 6 shown in FIG. 1.

As shown in FIG. 2, first transistor 106 has a rectangle shape in plan view. First transistor 106 is disposed near first output end 109 so as to face first harmonic processing element 103. As shown in FIG. 3, first transistor 106 has current terminal 107, control terminal 105, and a current terminal 110. The cross-sectional shape of first transistor 106 is substantially rectangular. First transistor 106 is an FET made of, for example, GaN or GaAs. Current terminal 107 and control terminal 105 have a rectangle shape in plan view.

Reference is made to FIGS. 2 and 4. Second fundamental matching element 203 has a rectangle shape in plan view and is disposed between second input end 201 and second output end 209. Second fundamental matching element 203 is disposed near second input end 201 with respect to second transistor 206. Second fundamental matching element 203 has a front-side metal film 222, a dielectric 223, and a back-side metal film 224. Front-side metal film 222 is provided on one surface of dielectric 223. Back-side metal film 224 is provided on the other surface of dielectric 223. The cross-sectional shape of second fundamental matching element 203 is substantially rectangular. Second fundamental matching element 203 constitutes a capacitor in which front-side metal film 222 is used as one electrode and back-side metal film 224 is used as the other electrode. Capacitance C of the capacitor is, for example, from 1 pF to 10 pF. This capacitor corresponds to second capacitor 16 shown in FIG. 1.

Second transistor 206 has a rectangle shape in plan view. Second transistor 206 is disposed between second input end 201 and second output end 209, and is disposed near second output end 209 so as to face second fundamental matching element 203. Second transistor 206 has current terminal 207, control terminal 205, and a current terminal 220. The cross-sectional shape of second transistor 206 is substantially rectangular. Second transistor 206 is an FET made of, for example, GaN or GaAs. Current terminal 207 and control terminal 205 have a rectangle shape in plan view.

Back-side metal film 114 of first harmonic processing element 103 and current terminal 110 of first transistor 106 are fixed on a mounting surface 52a of a base 52 while a conductive bonding material 111 is interposed between back-side metal film 114 and mounting surface 52a and conductive bonding material 111 is interposed between current terminal 110 and mounting surface 52a. Back-side metal film 224 of second fundamental matching element 203 and current terminal 220 of second transistor 206 are fixed on mounting surface 52a of base 52 while conductive bonding material 221 is interposed between back-side metal film 224 and mounting surface 52a and conductive bonding material 221 is interposed between current terminal 220 and mounting surface 52a. The material of conductive bonding material 111 and conductive bonding material 221 is, for example, AuSn or sintered Ag. The material of base 52 is, for example, metal. Base 52 has a plate shape and has a rectangle shape in plan view. Base 52 is defined as a reference potential and corresponds to reference potential line 7 in FIG. 1.

Referring again to FIG. 2, the connection relationship of the wires will be described. A wire 104 (first wire) connects front-side metal film 112 of first harmonic processing element 103 and control terminal 105, and is interposed between front-side metal film 112 of first harmonic processing element 103 and control terminal 105. A wire 108 (fourth wire) connects current terminal 107 and first output end 109, and is interposed between current terminal 107 and first output end 109. A wire 102 (sixth wire) connects first input end 101 and control terminal 105, and is interposed between first input end 101 and control terminal 105. Wire 102 extends over first harmonic processing elements 103.

In addition, a wire 202 (second wire) connects second input end 201 and front-side metal film 222 of second fundamental matching element 203, and is interposed between second input end 201 and front-side metal film 222 of second fundamental matching element 203. A wire 204 (third wire) connects front-side metal film 222 of second fundamental matching element 203 and control terminal 205, and is interposed between front-side metal film 222 of second fundamental matching element 203 and control terminal 205. A wire 208 (fifth wire) connects current terminal 207 and second output end 209, and is interposed between current terminal 207 and second output end 209.

The material of wire 102, wire 104, wire 202, wire 204, wire 108, and wire 208 is, for example, a gold wire. In addition, wire 102, wire 104, wire 202, wire 204, wire 108, and wire 208 are, for example, bonding wires.

The operation of main amplifier 100B having the above configuration will be described. Main amplifier 100B operates at all times. A signal input from first input end 101 is input to control terminal 105. When the signal is input to control terminal 105, first harmonic processing element 103 suppresses the harmonic included in the signal. The signal with the harmonic suppressed is amplified by first transistor 106. The amplified signal is output from first output end 109.

Peak amplifier 200B operates when an output larger than the saturation output of main amplifier 100B is required. The signal input from second input end 201 is input to control terminal 205. The signal is amplified by second transistor 206 and output from second output end 209. In second fundamental matching element 203 provided on the input side of second transistor 206, a reactance component included in the input impedance of second transistor 206 is matched.

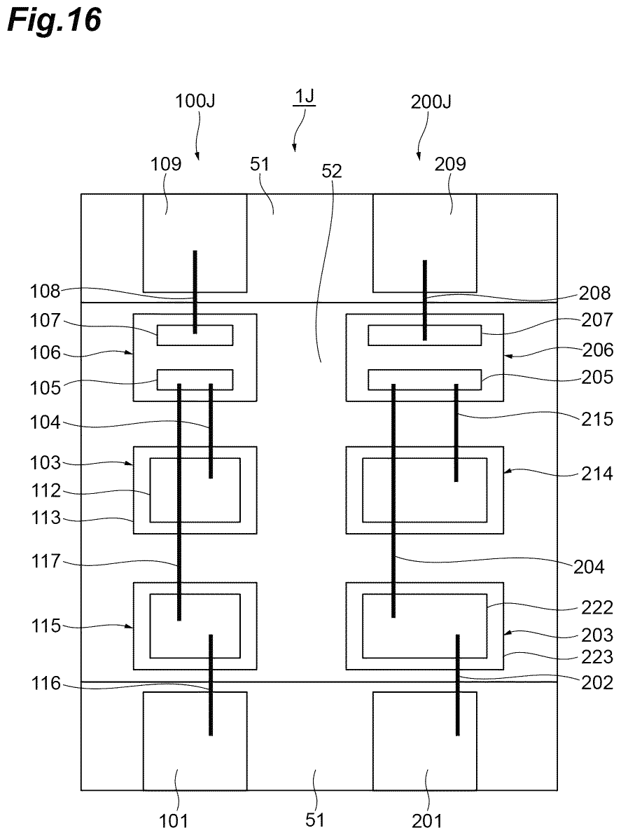

The effects of main amplifier 100B and peak amplifier 200B having the above configurations will be described with reference to FIG. 16. FIG. 16 is a plan view schematically showing a radio frequency amplifier device 1J, which is a comparative example. Radio frequency amplifier device 1J includes a main amplifier 100J and a peak amplifier 200J. Main amplifier 100J has both first harmonic processing element 103 and a first fundamental matching element 115 on the input side. At this time, a wire 116 is provided between first input end 101 and first fundamental matching element 115. A wire 117 connects control terminal 105 and first fundamental matching element 115, and is interposed between control terminal 105 and first fundamental matching element 115. Wire 117 extends over first harmonic processing element 103. Peak amplifier 200J has both a second harmonic processing element 214 and second fundamental matching element 203 on the input side. In this case, a wire 215 is provided between control terminal 205 and second harmonic processing element 214. Main amplifier 100J maintains high amplification efficiency by both first harmonic processing element 103 and first fundamental matching element 115. Peak amplifier 200J maintains high amplification efficiency by both second harmonic processing element 214 and second fundamental matching element 203. Compared with the Doherty amplifier having such a configuration, it is an object to provide a Doherty amplifier being downsized as well as maintaining high amplification efficiency. The efficiency of the main amplifier, which is a class A, class AB, or class B amplifier circuit, is lower than that of the amplifier, which is a class C amplifier circuit. Further, since the main amplifier is driven in the entire power range, the efficiency is likely to be reduced when the modulation signal is amplified. Therefore, in radio frequency amplifier device 1B according to the second embodiment of the present disclosure, the harmonic input to main amplifier 100B is suppressed by providing first harmonic processing element 103 in main amplifier 100B. This makes it difficult for the efficiency of main amplifier 100B to decrease. The peak amplifier is a class C amplifier circuit, and thus has high efficiency. Peak amplifier 200B can operate with high efficiency without being provided with second harmonic processing element 214. However, since the output of the peak amplifier is generally large, the mismatch of the input impedance of the transistor tends to be large. Therefore, the amplification efficiency of the peak amplifier is likely to decrease. Therefore, in the embodiment, second fundamental matching element 203 is provided in peak amplifier 200B. This suppresses the reduction in the amplification efficiency in peak amplifier 200B. Therefore, the reduction in the amplification efficiency in main amplifier 100B and peak amplifier 200B is suppressed, and radio frequency amplifier device 1B can be operated while maintaining high efficiency. Further, only first harmonic processing element 103 is provided on the input side of main amplifier 100B, and only second fundamental matching element 203 is provided on the input side of peak amplifier 200B. This reduces the number of elements to be mounted, and reduces the surface area of radio frequency amplifier device 1B. Therefore, radio frequency amplifier device 1B can be further miniaturized.

### (First Modification)

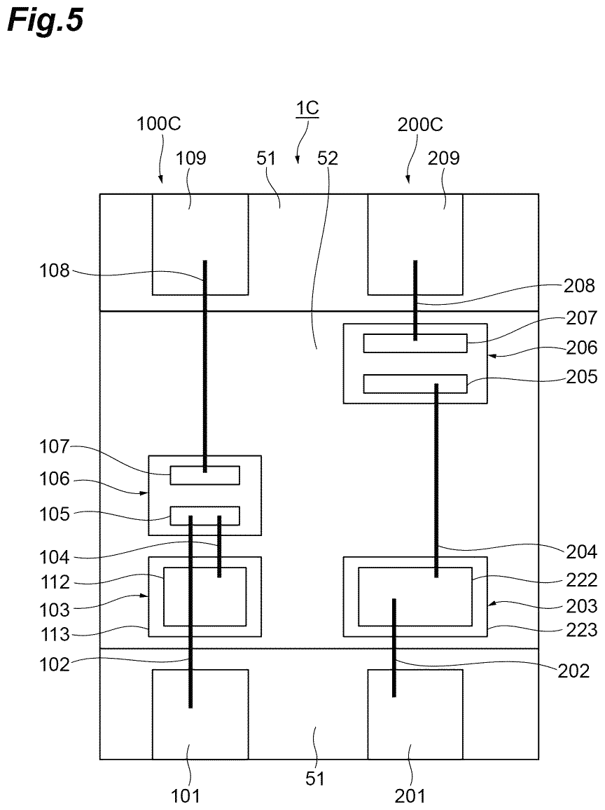

FIG. 5 is a plan view showing a radio frequency amplifier device 1C according to a first modification of a second embodiment. Radio frequency amplifier device 1C includes a main amplifier 100C and a peak amplifier 200C. Main amplifier 100C is different from main amplifier 100B in the following points, and is the same in other points. The peak amplifier 200C is different from peak amplifier 200B in the following points, and is the same in other points. In radio frequency amplifier device 1C, the length of wire 108 is longer than the length of wire 208. The length of wire 102 is shorter than the combined length of wire 202 and wire 204. An interval between first transistor 106 and first harmonic processing element 103 is smaller than an interval between second transistor 206 and second fundamental matching element 203. An interval between first transistor 106 and first output end 109 is greater than an interval between second transistor 206 and second output end 209.

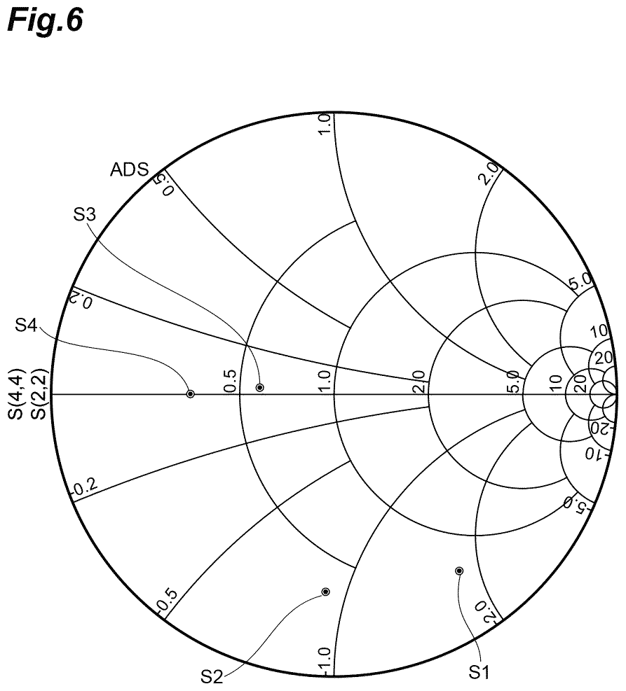

FIG. 6 is a Smith chart showing impedance characteristics in this modification. The output of peak amplifier 200C is larger than the output of main amplifier 100C. The output of main amplifier 100C is, for example, 5 W. The output of peak amplifier 200C is, for example, 10 W. The inductance included in wire 108 that is the wire on the output side of main amplifier 100C is, for example, 4 nH. The inductance included in wire 208 (fifth wire) which is the wire on the output side of peak amplifier 200C is, for example, 2 nH.

S1 is the impedance value of main amplifier 100B before the wire length is changed. S3 is the impedance value of main amplifier 100C after the wire length is changed. S2 is the impedance value of peak amplifier 200B before the wire length is changed. S4 is an impedance value of peak amplifier 200C after the wire length is changed. As described above, radio frequency amplifier device 1C can reduce the imaginary components of the impedances of main amplifier 100C and peak amplifier 200C. Therefore, impedance matching is facilitated.

### (Second Modification)

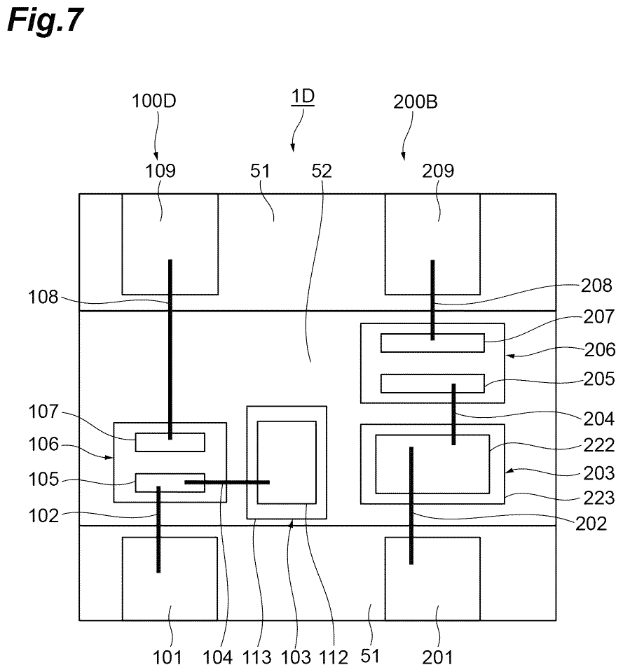

FIG. 7 is a plan view showing a radio frequency amplifier device ID according to a second modification. Radio frequency amplifier device ID includes a main amplifier 100D and peak amplifier 200B. Main amplifier 100D is different from main amplifier 100C in the following points, and is the same in other points. First harmonic processing element 103 is disposed between first transistor 106 and peak amplifier 200B. In this modification, the direction in which wire 104 extends and the direction in which wire 102 extends cross in plan view. In one embodiment, the direction in which wire 104 extends and the direction in which wire 102 extends are substantially orthogonal to each other in plan view. In this modification, the direction in which wire 104 extends and the direction in which wire 204 extends cross. In one embodiment, the direction in which wire 104 extends and the direction in which wire 204 extends are substantially orthogonal to each other. First harmonic processing element 103 is disposed between first transistor 106 and second fundamental matching element 203, for example.

The arrangement of FIG. 7 allows the interval between first transistor 106 and first input end 101 to be reduced. Therefore, radio frequency amplifier device ID can be further miniaturized. Further, such an arrangement suppresses the line capacitance between wire 104 and wire 102. This makes it possible to suppress line loss in wire 104 and wire 102. Therefore, it is possible to operate radio frequency amplifier device ID while maintaining higher efficiency.

### (Third Modification)

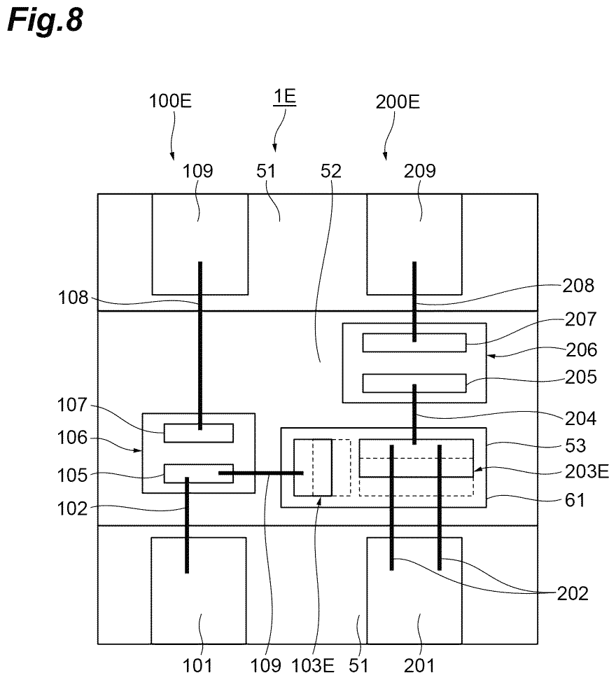

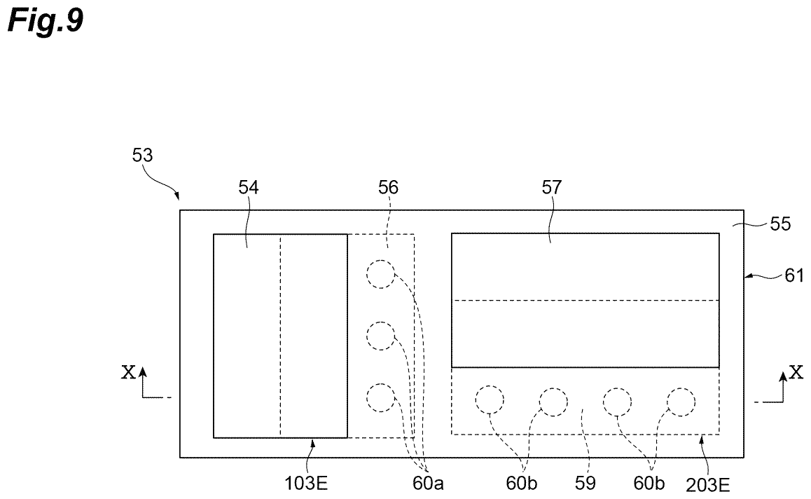

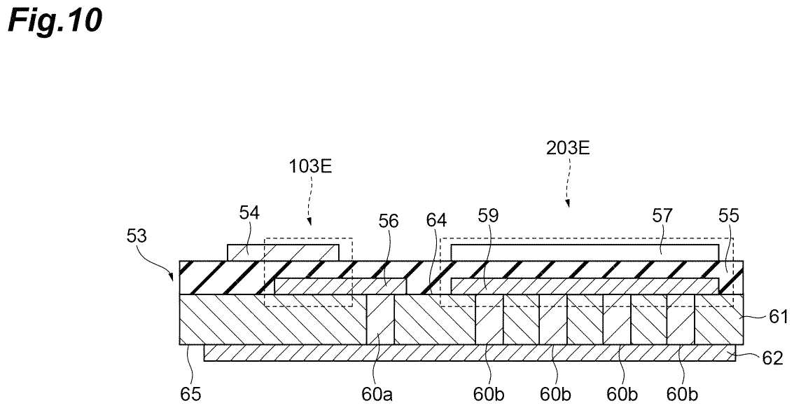

FIG. 8 is a plan view showing a radio frequency amplifier device 1E according to a third modification. FIG. 9 is an enlarged view showing the configuration of an integrated passive device 53. FIG. 10 is a cross-sectional view along line X-X shown in FIG. 9.

Radio frequency amplifier device 1E of this modification includes a main amplifier 100E and a peak amplifier 200E. Main amplifier 100E is different from main amplifier 100D in the following points, and is the same in the other points. Peak amplifier 200E is different from peak amplifier 200B in the following points, and is the same in other points. Radio frequency amplifier device 1E includes integrated passive device 53. Integrated passive device 53 has a first harmonic processing element 103E, a second fundamental matching element 203E, and a substrate 61. The material of substrate 61 is, for example, GaAs or Si. Substrate 61 has a plate shape and has a rectangle shape in plan view. Substrate 61 has a surface 64 and a surface 65. First harmonic processing element 103E and second fundamental matching element 203E are provided on surface 64.

As shown in FIGS. 9 and 10, a second metal film 56 and a fourth metal film 59 are provided on surface 64. Further, a dielectric film 55 is provided on second metal film 56 and fourth metal film 59. Dielectric film 55 is in contact with surface 64. A first metal film 54 and a third metal film 57 are provided on dielectric film 55. Referring to FIGS. 8 and 9, the distance between first metal film 54 and second fundamental matching element 203E is longer than the distance between second metal film 56 and second fundamental matching element 203E. The distance between first metal film 54 and first transistor 106 is shorter than the distance between second metal film 56 and first transistor 106. The distance between third metal film 57 and second transistor 206 is shorter than the distance between fourth metal film 59 and second transistor 206. The distance between third metal film 57 and second input end 201 is longer than the distance between fourth metal film 59 and second input end 201. First metal film 54, second metal film 56, third metal film 57, and fourth metal film 59 have a film shape and have a rectangle shape in plan view. The material of first metal film 54, second metal film 56, third metal film 57, and fourth metal film 59 is, for example, gold. Dielectric film 55 has a film shape and has a rectangle shape in plan view. The material of dielectric film 55 is, for example, SiN. First harmonic processing element 103E is constituted by a portion where first metal film 54 and second metal film 56 face each other, and dielectric film 55. Second fundamental matching element 203E is constituted by a portion where third metal film 57 and fourth metal film 59 face each other, and dielectric film 55.

As shown in FIGS. 9 and 10, integrated passive device 53 includes a plurality of vias 60a, a plurality of vias 60b and a back-side metal film 62 in addition to substrate 61. The plurality of vias 60a are connected to second metal film 56. The plurality of vias 60b are connected to fourth metal film 59. Back-side metal film 62 is provided on surface 65. Back-side metal film 62 is connected to the plurality of vias 60a and the plurality of vias 60b. Back-side metal film 62 is connected to base 52 with a conductive bonding material (not shown) interposed therebeween. The material of back-side metal film 62 is, for example, gold. The plurality of vias 60a and the plurality of vias 60b penetrate from surface 64 to surface 65. The plurality of vias 60a and the plurality of vias 60b have a circular shape in plan view and have a rectangle shape in the cross-sectional surface. The material of the plurality of vias 60a and the plurality of vias 60b is, for example, gold. In plan view, the plurality of vias 60a are accommodated inside second metal film 56. In plan view, the plurality of vias 60b are accommodated inside fourth metal film 59.

The configuration of FIG. 8 reduces the surface area of the elements included in radio frequency amplifier device 1E, and thus radio frequency amplifier device 1E can be further miniaturized. First metal film 54, second metal film 56, and dielectric film 55 form a capacitor with the potential of second metal film 56 as a reference. First harmonic processing element 103E includes the capacitor. Third metal film 57, fourth metal film 59, and dielectric film 55 form a capacitor with the potential of fourth metal film 59 as a reference. Second fundamental matching element 203E has the capacitor. First harmonic processing element 103E and second fundamental matching element 203E are provided on surface 64. Thus, integrated passive device 53 can be realized.

### (Fourth Modification)

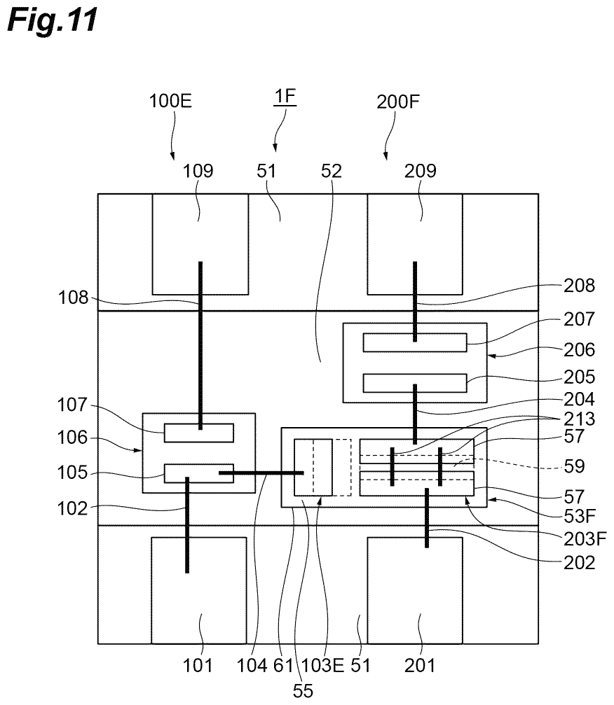

FIG. 11 is a plan view showing a radio frequency amplifier device IF according to a fourth modification. In FIG. 11, radio frequency amplifier device IF includes main amplifier 100E and a peak amplifier 200F. Peak amplifier 200F is different from peak amplifier 200E in the following points, and is the same in other points. Radio frequency amplifier device IF has an integrated passive device 53F instead of integrated passive device 53. Integrated passive device 53F has first harmonic processing element 103E and a second fundamental matching element 203F. Second fundamental matching element 203F in this modification has two third metal films 57, dielectric film 55, and one fourth metal film 59. Fourth metal film 59 is provided on substrate 61. Dielectric film 55 is provided on fourth metal film 59. Dielectric film 55 is in contact with substrate 61. Two third metal films 57 are provided on dielectric film 55. Fourth metal film 59, dielectric film 55, and one of third metal films 57 form a capacitor, and fourth metal film 59, dielectric film 55, and the other third metal film 57 form another capacitor. One of third metal films 57 and the other third metal film 57 are connected to each other by two wires 213. This makes it possible to suppress the input impedance mismatch of the transistor in the peak amplifier in a wider band.

### (Fifth Modification)

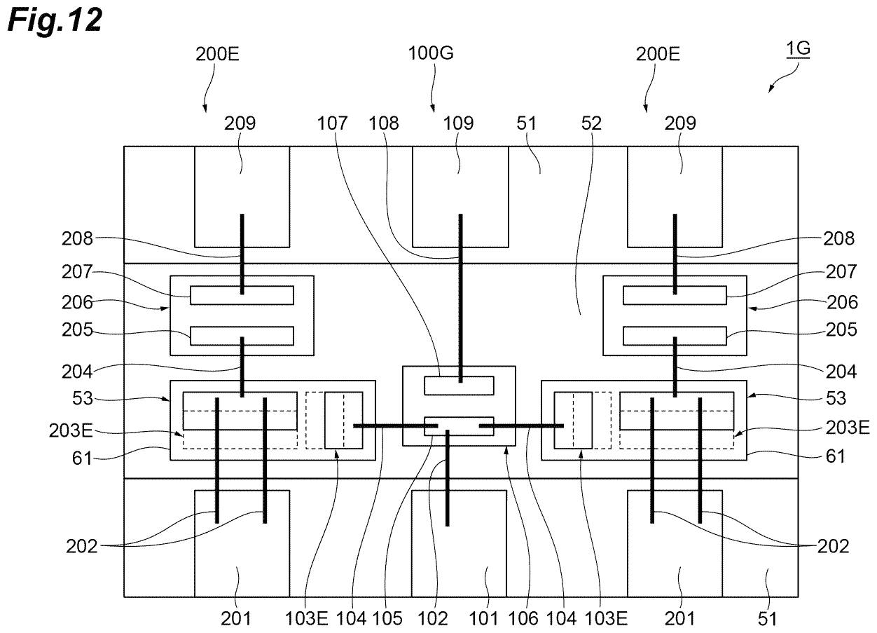

FIG. 12 is a plan view showing a radio frequency amplifier device 1G according to a fifth modification. Radio frequency amplifier device 1G in this modification includes one main amplifier 100G and two peak amplifiers 200E. Main amplifier 100G is different from main amplifier 100E in the following points, and is the same in the other points. Main amplifier 100G is arranged between two peak amplifiers 200E. First transistor 106 is arranged between two first harmonic processing elements 103E. In integrated passive device 53, first harmonic processing element 103E is arranged near first transistor 106 with respect to second fundamental matching element 203E. Main amplifier 100G has two first harmonic processing elements 103E.

By mounting two peak amplifiers 200E in radio frequency amplifier device 1G and mounting two first harmonic processing elements 103E in main amplifier 100G, the second harmonic input to radio frequency amplifier device 1G is suppressed. Furthermore, first harmonic processing element 103E is connected to control terminal 105 by wire 104. First harmonic processing elements 103E are arranged on both sides of first transistor 106 so that first transistor 106 is interposed between first harmonic processing elements 103E. This arrangement suppresses the second harmonic. Therefore, the imbalance of the harmonic suppression is reduced.

### (Sixth Modification)

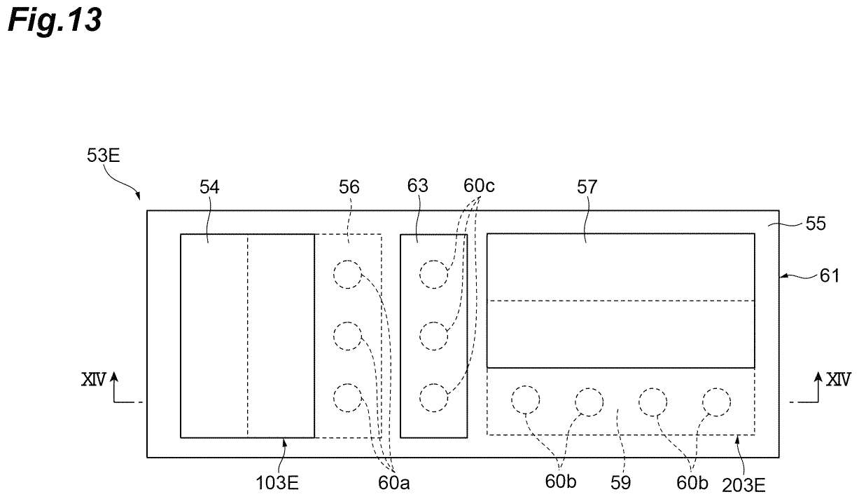

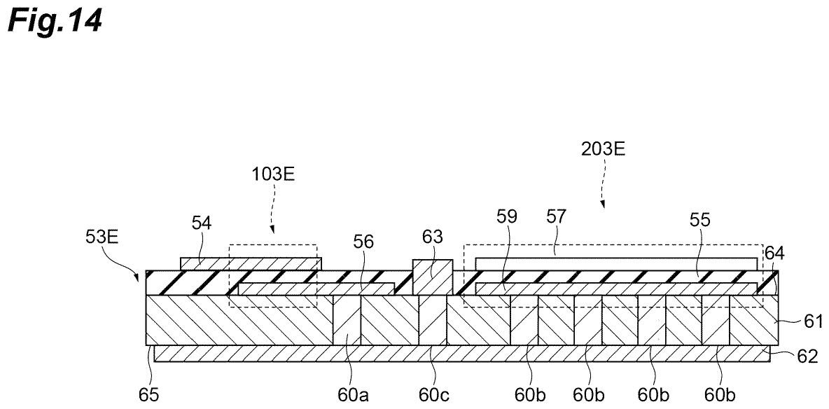

FIG. 13 is an enlarged view showing a modification of an integrated passive device. FIG. 14 is a cross-sectional view along line XIV-XIV shown in FIG. 13. An integrated passive device 53E of FIG. 13 has a fifth metal film 63 in addition to the configuration of FIG. 9. Fifth metal film 63 is provided on surface 64 between first harmonic processing element 103E and second fundamental matching element 203E. In FIG. 14, fifth metal film 63 is provided so as to be surrounded by dielectric film 55. Further, as shown in FIG. 14, integrated passive device 53E includes substrate 61, the plurality of vias 60a, the plurality of vias 60b, the plurality of vias 60c, and back-side metal film 62. The plurality of vias 60c are provided on substrate 61 and connected to fifth metal film 63. Back-side metal film 62 is provided on surface 65 and is connected to the plurality of vias 60c. Fifth metal film 63 has a film shape and has a rectangle shape in plan view.

Fifth metal film 63 connected to a reference potential is provided between first harmonic processing element 103E and second fundamental matching element 203E. This makes it possible to suppress electromagnetic interference between main amplifier 100E and peak amplifier 200E. In addition, fifth metal film 63 and the plurality of vias 60c are connected, and the plurality of vias 60c and back-side metal film 62 connected to the reference potential are connected. As a result, fifth metal film 63 can be set to the reference potential.

What is claimed is:

1. A radio frequency amplifier circuit comprising: a Doherty amplifier including a main amplifier and a peak amplifier,
the main amplifier including:
a first input end;
a first output end;
a first transistor having a control terminal connected to the first input end and a current terminal connected to the first output end; and
only a first harmonic processing circuit among the first harmonic processing circuit and a first fundamental matching circuit, the first harmonic processing circuit being connected to the control terminal of the first transistor and configured to suppress a harmonic to be input to the first transistor, the first fundamental matching circuit being connected between the first input end and the control terminal of the first transistor and configured to attain matching with an input impedance of the first transistor,
the peak amplifier including:
a second input end;
a second output end;
a second transistor having a control terminal connected to the second input end and a current terminal connected to the second output end; and
only a second fundamental matching circuit among a second harmonic processing circuit and the second fundamental matching circuit, the second harmonic processing circuit being connected to the control terminal of the second transistor and configured to suppress a harmonic to be input to the second transistor, the second fundamental matching circuit being connected between the second input end and the control terminal of the second transistor and configured to attain matching with an input impedance of the second transistor.

2. The radio frequency amplifier circuit according to claim 1, wherein
the first harmonic processing circuit includes:
a first capacitor having one electrode connected to a reference potential; and
a first wire configured to connect another electrode of the first capacitor with the control terminal of the first transistor and including a first inductance, and
the second fundamental matching circuit includes:
a second capacitor having one electrode connected to the reference potential;
a second wire configured to connect another electrode of the second capacitor with the second input end and including a second inductance; and
a third wire configured to connect the control terminal of the second transistor with the another electrode of the second capacitor and including a third inductance.

3. A radio frequency amplifier device comprising: a Doherty amplifier including a main amplifier and a peak amplifier,
the main amplifier including:
a first input end;
a first output end;
a first transistor having a control terminal connected to the first input end and a current terminal connected to the first output end; and
only a first harmonic processing element among the first harmonic processing element and a first fundamental matching element, the first harmonic processing element being connected to the control terminal of the first transistor and configured to suppress a harmonic to be input to the first transistor, the first fundamental matching element being connected between the first input end and the control terminal of the first transistor and configured to attain matching with an input impedance of the first transistor,
the peak amplifier including:
a second input end;
a second output end;
a second transistor having a control terminal connected to the second input end and a current terminal connected to the second output end; and
only a second fundamental matching element among a second harmonic processing element and the second fundamental matching element, the second harmonic processing element being connected to the control terminal of the second transistor and configured to suppress a harmonic to be input to the second transistor, the second fundamental matching element being connected between the second input end and the control terminal of the second transistor and configured to attain matching with an input impedance of the second transistor.

4. The radio frequency amplifier device according to claim 3, wherein an output of the peak amplifier is larger than an output of the main amplifier.

5. The radio frequency amplifier device according to claim 4, wherein
the main amplifier includes:
a fourth wire configured to make a connection between the first output end and the current terminal of the first transistor,
the peak amplifier includes:
a fifth wire configured to make a connection between the second output end and the current terminal of the second transistor, and
the fourth wire has a length longer than a length of the fifth wire.

6. The radio frequency amplifier device according to claim 3, wherein the first harmonic processing element is disposed between the first transistor and the peak amplifier.

7. The radio frequency amplifier device according to claim 6, wherein
the main amplifier includes:
a first wire configured to make a connection between the control terminal of the first transistor and the first harmonic processing element; and
a sixth wire configured to make a connection between the first input end and the control terminal of the first transistor, and
a direction in which the first wire extends and a direction in which the sixth wire extends cross in plan view.

8. The radio frequency amplifier device according to claim 6, further comprising: an integrated passive device including the first harmonic processing element and the second fundamental matching element.

9. The radio frequency amplifier device according to claim 8, wherein
the integrated passive device includes:
a substrate;
a second metal film and a fourth metal film that are provided on one surface of the substrate;
a dielectric film provided on the second metal film and the fourth metal film; and
a first metal film and a third metal film that are provided on the dielectric film,
the first harmonic processing element is constituted by the second metal film, the dielectric film, and the first metal film,
the second fundamental matching element is constituted by the fourth metal film, the dielectric film, and the third metal film,
the first metal film and the control terminal of the first transistor are connected to each other,
the third metal film and the control terminal of the second transistor are connected to each other, and
the second metal film and the fourth metal film are connected to a reference potential.

10. The radio frequency amplifier device according to claim 9, wherein the integrated passive device includes a fifth metal film provided on the one surface between the first harmonic processing element and the second fundamental matching element and connected to the reference potential.

11. The radio frequency amplifier device according to claim 10, wherein
the integrated passive device includes:
a via provided in the substrate and connected to the fifth metal film; and
a back-side metal film provided on a surface opposite to the one surface and connected to the via and the reference potential.
